(19) United States
(12) Patent Application Publication
(10) Pub. No.: US 2025/0192094 A1
(43) Pub. Date: Jun. 12, 2025

(54) SEMICONDUCTOR PACKAGE

(71) Applicant: SAMSUNG ELECTRONICS CO., LTD., Suwon-si (KR)

(72) Inventors: Wonil Seo, Suwon-si (KR); Jiwon Shin, Suwon-si (KR)

(21) Appl. No.: 18/966,718

(22) Filed: Dec. 3, 2024

(30) Foreign Application Priority Data
Dec. 8, 2023 (KR) 10-2023-0177362

(51) Int. Cl. H01L 23/00; H01L 23/31; H01L 23/538; H01L 25/00; H01L 25/07; H10B 80/00

(52) U.S. Cl. CPC H01L 24/48; H01L 23/5383; H01L 25/074; H01L 25/50; H01L 23/3142; H01L 24/45; H01L 2224/45124; H01L 2224/45144; H01L 2224/45147; H01L 2224/48227; H01L 2224/48483; H01L 2225/06562; H10B 80/00

(57) ABSTRACT

A semiconductor package includes a package substrate, an encapsulation structure stacked on the package substrate, a plurality of conductive bumps disposed between the package substrate and the encapsulation structure, and an adhesive layer attaching the package substrate and the encapsulation structure to each other. The encapsulation structure includes a sealing member having an upper surface and a lower surface opposite to each other, a plurality of semiconductor chips sequentially arranged in the sealing member such that a front surface on which chip pads are formed faces the package substrate, and conductive wires extending from a lower surface of the sealing member to the chip pads of the plurality of semiconductor chips. The plurality of conductive bumps are disposed between the conductive wires and substrate pads of the package substrate.

### CROSS-REFERENCE TO RELATED APPLICATION(S)

This application claims priority under 35 U.S.C. § 119 to Korean Patent Application No. 10-2023-0177362, filed on Dec. 8, 2023 in the Korean Intellectual Property Office (KIPO), the contents of which are herein incorporated by reference in their entirety.

### BACKGROUND

In manufacturing a multi-chip package, a plurality of semiconductor chips may be stacked on a package substrate and the semiconductor chips may be electrically connected to the package substrate using bonding wires. The bonding wires may extend outward from one surface of the semiconductor chip and be bonded to substrate pads of the package substrate. Accordingly, a vertical space may be desired for loop heights of the bonding wires, and since the bonding wires extend beyond the area where the semiconductor chip is placed, an outer area around the semiconductor chip may be desired for the bonding wires. Thus, a space may be desired in horizontal and vertical directions for bonding wires, making it difficult to reduce the package.

### SUMMARY

Implementations provide a semiconductor package with a small form factor package structure and improved electrical characteristics.

Implementations provide a method of manufacturing the semiconductor package.

According to some implementations, a semiconductor package includes a package substrate, an encapsulation structure stacked on the package substrate, a plurality of conductive bumps disposed between the package substrate and the encapsulation structure, and an adhesive layer attaching the package substrate and the encapsulation structure to each other. The encapsulation structure includes a sealing member having an upper surface and a lower surface opposite to each other, a plurality of semiconductor chips sequentially arranged in the sealing member such that a front surface on which chip pads are formed faces the package substrate, and conductive wires extending from a lower surface of the sealing member to the chip pads of the plurality of semiconductor chips. The plurality of conductive bumps are disposed between the conductive wires and substrate pads of the package substrate.

According to some implementations, a semiconductor package includes a package substrate having substrate pads on an upper surface of the package substrate, a sealing member stacked on the upper surface of the package substrate via conductive bumps that are disposed on the substrate pads, a plurality of semiconductor chips sequentially stacked in the sealing member and arranged such that a front surface on which chip pads are formed faces the package substrate, and conductive wires extending from a lower surface of the sealing member to the chip pads of the plurality of semiconductor chips. The plurality of conductive bumps are disposed between the conductive wires and the substrate pads.

According to some implementations, a semiconductor package includes a package substrate having substrate pads on an upper surface of the package substrate; an encapsulation structure stacked on the package substrate, and including a sealing member having an upper surface and a lower surface opposite to each other, a plurality of semiconductor chips sequentially stacked in the sealing member, offset aligned in a horizontal direction with respect to each other and arranged such that a front surface on which chip pads are formed faces the package substrate, and conductive wires extending from a lower surface of the sealing member to the chip pads of the plurality of semiconductor chips; a plurality of conductive bumps disposed between the package substrate and the encapsulation structure and electrically connecting the substrate pads and the conductive wires; and an adhesive layer attaching the package substrate and the encapsulation structure to each other.

According to some implementations, a semiconductor package may include a package substrate, an encapsulation structure stacked on the package substrate via conductive bumps, and an adhesive layer interposed between the package substrate and the encapsulation structure. The encapsulation structure may include a sealing member, a plurality of semiconductor chips disposed in a sealing member, a plurality of semiconductor chips stacked from a lower surface of the sealing member in the sealing member, and conductive wires extending in a vertical direction from the lower surface of the sealing member to chip pads of the plurality of the semiconductor chips. The chip pads of the plurality of semiconductor chips may be electrically connected to upper substrate pads of the package substrate by the conductive wires and the conductive bumps.

The conductive wires may extend vertically and may not extend outward from one side of each of the plurality of semiconductor chips. Accordingly, since the conductive wires do not need an outer area around the semiconductor chips, the area and height of the sealing member surrounding the conductive wires may be formed to be smaller. Thus, it may be possible to implement a small form factor package. Further, since the conductive wires extend in the vertical direction, the connection passages may become very short, thereby greatly reducing the inductance of the electrical signal path and improving electrical performance. Furthermore, since the encapsulation structure is stacked on the package substrate via the conductive bumps, a separate redistribution wiring layer may not be required, thereby simplifying the package manufacturing process.

### BRIEF DESCRIPTION OF THE DRAWINGS

Implementations will be more clearly understood from the following detailed description taken in conjunction with the accompanying drawings.

FIG. 1 is a cross-sectional view illustrating a semiconductor package in accordance with some implementations.

FIG. 2 is a FIG. 2 is an enlarged cross-sectional view illustrating portion ‘A’ in FIG. 1.

FIGS. 3 to 13 are views illustrating a method of manufacturing a semiconductor package in accordance with some implementations.

FIG. 14 is a cross-sectional view illustrating a semiconductor package in accordance with some implementations.

FIG. 15 is an enlarged cross-sectional view illustrating a portion ‘C’ in FIG. 14.

FIG. 16 is a cross-sectional view illustrating a method of manufacturing a semiconductor package in accordance with some implementations.

FIG. 17 is a cross-sectional view illustrating a semiconductor package in accordance with some implementations.

FIGS. 18 to 22 are views illustrating a method of manufacturing a semiconductor package in accordance with some implementations.

### DETAILED DESCRIPTION

Hereinafter, implementations will be explained in detail with reference to the accompanying drawings.

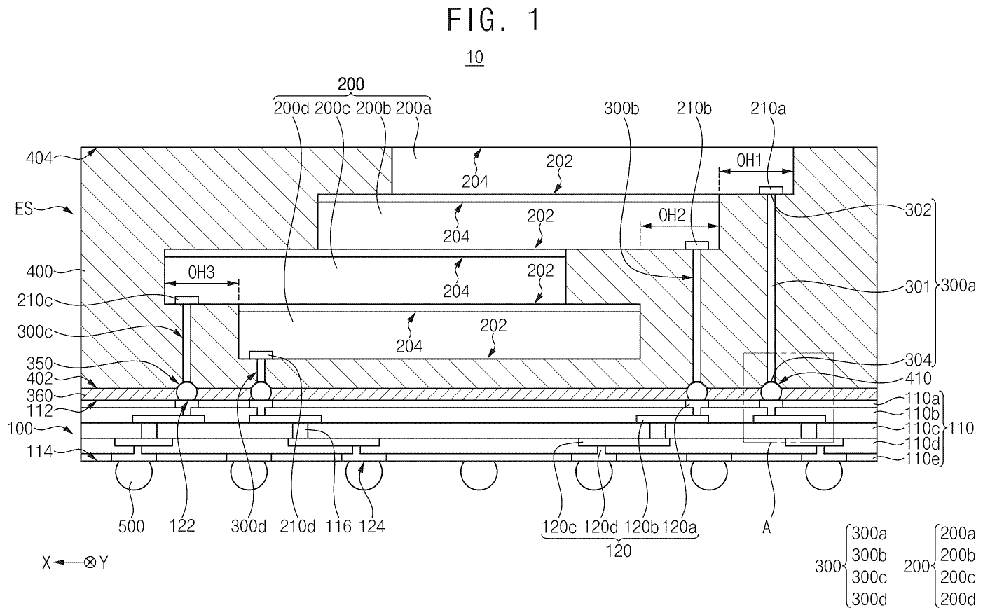

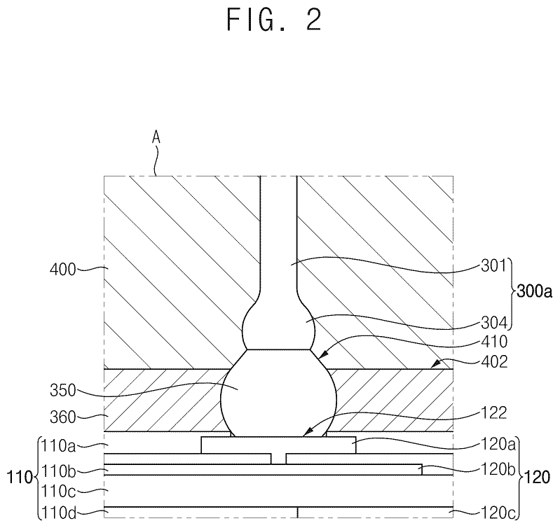

FIG. 1 is a cross-sectional view illustrating a semiconductor package in accordance with some implementations. FIG. 2 is an enlarged cross-sectional view illustrating portion ‘A’ in FIG. 1.

Referring to FIGS. 1 and 2, a semiconductor package 10 includes a package substrate 100, a encapsulation structure ES disposed on the package substrate 100, a plurality of conductive bumps 350 disposed between the package substrate 100 and the encapsulation structure ES, and an adhesive layer 360 attaching the package substrate 100 and the encapsulation structure ES to each other. The encapsulation structure ES includes a sealing member 400, a plurality of semiconductor chips 200 disposed in the sealing member 400, and conductive wires 300 as a plurality of vertical conductive structures in the sealing member 400 and extending from chip pads 210 of the plurality of semiconductor chips 200. Additionally, the semiconductor package 10 further includes external connection members 500 disposed on an outer surface of the package substrate 100.

In some implementations, the package substrate 100 may be a multilayer circuit board having an upper surface 112 and a lower surface 114 opposite to the upper surface 112. The package substrate 100 may include a printed circuit board (PCB), a flexible substrate, a tape substrate, etc. The package substrate 100 may include a plurality of stacked insulating layers 110 and wirings 120 respectively provided in the insulating layers.

In particular, the package substrate 100 includes first to fifth insulating layers 110a, 110b, 110c, 110d, and 110e sequentially stacked. The first insulating layer 110a may be an upper cover insulating layer, the second insulating layer 110b may be an upper insulating layer, the third insulating layer 110c may be a core layer, the fourth insulating layer 110d may be a lower insulating layer, and the fifth insulating layer 110e may be a lower cover insulating layer.

The third insulating layer 110c as the core layer may include a non-conductive material layer. The third insulating layer 110c may include a reinforcing polymer or the like. The third insulating layer 110c may serve as a boundary layer dividing an upper portion and a lower portion of the package substrate 100.

A second wiring 120b may be formed on an upper surface of the third insulating layer 10c. The second insulating layer 10b may be formed on the upper surface of the third insulating layer 10c to cover the second wiring 120b. A first wiring 120a may be formed on an upper surface of the second insulating layer 110b, and may be electrically connected to the second wiring 120b through an opening formed in the second insulating layer 110b.

A third wiring 120c may be formed on a lower surface of the third insulating layer 10c. The fourth insulating layer 110d may be formed on the lower surface of the third insulating layer 10c to cover the third wiring 120c. A fourth wiring 120d may be formed on a lower surface of the fourth insulating layer 10d, and may be electrically connected to the third wiring 120c through an opening formed in the fourth insulating layer 110d.

The first to fourth wirings 120a, 120b, 120c and 120d may be referred to as first to fourth circuit layers stacked in a thickness direction from the upper surface 112 to the lower surface 114 of the package substrate 100. For example, the wiring may include metal materials such as copper, aluminum, etc. It will be understood that the arrangements and numbers of the insulating layers and the wirings are illustrative and not limited thereto.

A conductive through via 116 may penetrate the third insulating layer 110c as the core layer and electrically connect the second wiring 120b and the third wiring 120c. The first wiring 120a may be exposed from the upper surface 112 of the package substrate 100. The fourth wiring 120d may be exposed from the lower surface 114 of the package substrate 100.

The first insulating layer 110a as an upper protective layer may be formed on the upper surface 112 of the package substrate 100, and may expose at least a portion of the first wiring 120a. The exposed portion of the first wiring 120a may be provided as an upper substrate pad 122. The fifth insulating layer 110e as a lower protective layer may be provided on the lower surface 114 of the package substrate 100, and may expose at least a portion of the fourth wiring 120d. The exposed portion of the fourth wiring 120d may be provided as a lower substrate pad 124. The upper insulating layer 110a and the lower insulating layer 110e may separate the circuit patterns of the package substrate 100 from the external environment to prevent contamination and electrically insulate the wirings of the circuit patterns from each other. For example, the upper insulating layer and the lower insulating layer may include a photosensitive resin such as photo epoxy or a photosensitive polymer such as photo solder resist (PSR).

In some implementations, the encapsulation structure ES includes the sealing member 400, the plurality of semiconductor chips 200 sequentially stacked within the sealing member 400 from an upper surface 404 of the sealing member 400, and the conductive wires 300 extending within the sealing member 400 from a lower surface 402 of the sealing member 400 to the chip pads 210 of the plurality of semiconductor chips 200.

The plurality of semiconductor chips 200 may be sequentially stacked within the sealing member 400. The plurality of semiconductor chips 200 may be arranged such that a front surface 202 on which the chip pads 210 are formed faces the package substrate 100. Each of semiconductor chips 200 may have a rectangular shape with four sides when viewed in plan view.

The chip pads 210 may be disposed in a peripheral region along one side of each of the semiconductor chips 200.

In particular, the plurality of semiconductor chips 200 includes first, second, third, and fourth semiconductor chips 200a, 200b, 200c, and 200d stacked in a cascade structure from the upper surface 404 of the sealing member 400. The second, third, and fourth semiconductor chips 200b, 200c, and 200d may be sequentially attached to the first semiconductor chip 200a using adhesive films 220. The adhesive films may include die attach film (DAF). For example, a thickness of the semiconductor chip may be within a range of 40 μm to 110 μm. The thickness of the adhesive film may be within a range of 10 μm to 60 μm.

The second semiconductor chip 200b may be offset aligned in a first horizontal direction (X direction) with respect to the first semiconductor chip 200a. The second semiconductor chip 200b may be offset aligned in the first horizontal direction (X direction) such that the chip pad 210a of the first semiconductor chip 200a is exposed from the second semiconductor chip 200b. The third semiconductor chip 200c may be offset aligned in the first horizontal direction (X direction) with respect to the second semiconductor chip 200b. The third semiconductor chip 200c may be offset aligned in the first horizontal direction (X direction) such that the chip pad 210b of the second semiconductor chip 200b is exposed from the third semiconductor chip 200c. The fourth semiconductor chip 200d may be offset aligned in a direction opposite to the first horizontal direction (X direction) with respect to the third semiconductor chip 200c. The fourth semiconductor chip 200d may be offset aligned in the direction opposite to the first horizontal direction (X direction) such that the chip pad 210c of the third semiconductor chip 200c is exposed from the fourth semiconductor chip 200d.

Each of the first, second, and third semiconductor chips 200a, 200b, and 200c may have an overhang portion OH1, OH2, OH3 protruding from one side of each of the underlying second, third, and fourth semiconductor chips 200b, 200c, and 200d. When viewed from bottom view, the chip pad 210a of the first semiconductor chip 200a may be arranged on a lower surface (that is, the front surface 202) of the overhang portion OH1 protruding from one side of the second, third, and fourth semiconductor chips 200b, 200c, and 200d to be spaced apart from each other along a second horizontal direction (Y direction) perpendicular to the first horizontal direction. When viewed from bottom view, the chip pad 210b of the second semiconductor chip 200b may be arranged on a lower surface (that is, the front surface 202) of the overhang portion OH2 protruding from one side of the third and fourth semiconductor chips 200c and 200d to be spaced apart from each other along the second horizontal direction (Y direction). When viewed from bottom view, the chip pad 210c of the third semiconductor chip 200c may be arranged on a lower surface (that is, the front surface 202) of the overhang portion OH3 protruding from one side of the fourth semiconductor chip 200d to be spaced apart from each other along the second horizontal direction (Y direction).

The plurality of semiconductor chips 200 may include a memory chip including a memory circuits. For example, the semiconductor chip may include volatile memory devices such as SRAM devices or DRAM devices, and non-volatile memory devices such as flash memory devices, PRAM devices, MRAM devices or RRAM devices.

It will be understood that the number, size, arrangement, etc. of the semiconductor chips are provided as an example, and the present disclosure is not limited thereto. Also, although only a few chip pads are illustrated in the figures, it will be understood that the structure, shape, and arrangement of the chip pads are provided as an example, and the present disclosure is not limited thereto.

In some implementations, the conductive wires 300 may extend vertically on the chip pads 210 of the first, second, third, and fourth semiconductor chips 200 within the sealing member 400, respectively. When viewed from a bottom view, the conductive wires 300 may be positioned in an area where the plurality of semiconductor chips 200 are disposed.

In particular, the first conductive wire 300a may be a conductive wire that extends from the chip pad 210a of the first semiconductor chip 200a to the lower surface 402 of the sealing member 400. The second conductive wire 300b may be a conductive wire that extends from the chip pad 210b of the second semiconductor chip 200b to the lower surface 402 of the sealing member 400. The third conductive wire 300c may be a conductive wire that extends from the chip pad 210c of the third semiconductor chip 200c to the lower surface 402 of the sealing member 400. The fourth conductive wire 300d may be a conductive wire that extends from the chip pad 210d of the fourth semiconductor chip 200d to the lower surface 402 of the sealing member 400. The first, second, third and fourth conductive wires may be formed by a bonding wire process. For example, the conductive wire may include copper (Cu), gold (Au), aluminum (Al), etc.

As illustrated in FIG. 2, the conductive wire 300a includes a wire body 301 extending in a vertical direction, a first bonding end portion 302 provided at a first end portion of the wire body 301 and bonded to the first chip pad 210a, and a second bonding end portion 304 provided at a second end portion opposite to the first end portion of the wire body 301 and having a ball shape. The wire body 301 may have a first diameter, and the second bonding end portion 304 may have a second diameter that is greater than the first diameter. For example, the first diameter and the second diameter may be within a range of 15 μm to 200 μm.

Recesses 410 may be provided in the lower surface 402 of the sealing member 400 and may respectively expose end portions of the conductive wires 300, that is, the second bonding end portions 304. For example, the recesses 410 may be formed by performing a laser drilling process on the lower surface 402 of the sealing member 400. The recesses 410 may have a predetermined depth from the lower surface 402 of the molding member 400 and may expose the end portions of the plurality of conductive wires 300. The depth of the recess 410 may be within a range of 15 m to 100 μm from the lower surface 402 of the molding member 400.

In some implementations, the encapsulation structure ES including the sealing member 400 covering the plurality of semiconductor chips 200 and the plurality of conductive wires 300 may be stacked on the package substrate 100 via conductive bumps 350. The encapsulation structure ES may be stacked on the package substrate 100 such that the lower surface 402 of the sealing member 400 faces the package substrate 100.

The conductive bumps 350 may be interposed between the encapsulation structure ES and the package substrate 100. The conductive bumps 350 may be interposed between upper bonding pads 122 of the package substrate 100 and the conductive wires 300 of the package substrate 100 respectively. The conductive bumps 350 and the conductive wires 300 may electrically connect the chip pads 210 of the semiconductor chips 200 and the wirings 120 of the package substrate 100. Portions of the conductive bumps 350 may be bonded to the exposed end portions of the conductive wires 300, i.e., the second bonding end portions 304 in the recesses 410 of the sealing member 400.

In some implementations, the encapsulation structure ES may be attached to the package substrate 100 using an adhesive layer 360. The adhesive layer 360 as a gap-fill material layer may be filled between the encapsulation structure ES and the package substrate 100. The adhesive layer 360 may cover side surfaces of the conductive bumps 350.

For example, the adhesive layer 360 may include a non-conductive adhesive film (Non Conductive Film, NCF). By thermal compression of a bonding apparatus, bumps on the conductive wires 300 may be reflowed to form the conductive bumps 350, and the encapsulation structure ES and the package substrate 100 may be attached by the adhesive layer 360. The adhesive layer 360 may have a thickness within the range of 10 μm to 150 μm.

For example, the conductive bump 350 may have a diameter within a range of 15 μm to 200 μm. A diameter of the upper substrate pad 122 may be the same as the diameter of the conductive bump 350. Alternatively, the diameter of the upper substrate pad 122 may be greater or less than the diameter of the conductive bump 350.

In some implementations, external connection members 500 may be disposed on lower substrate pads 124 on the lower surface 114 of the package substrate 100. For example, the external connection member 500 may include a solder ball. The solder ball may have a diameter of 300 μm to 500 μm. The semiconductor package 10 may be mounted on a module substrate using the solder balls to form a memory module.

As mentioned above, the semiconductor package 10 includes the package substrate 100, the encapsulation structure ES stacked on the package substrate 100 via the conductive bumps 350, and the adhesive layer 360 interposed between the package substrate 100 and the encapsulation structure ES. The encapsulation structure ES includes the sealing member 400, the plurality of semiconductor chips 200 disposed in the sealing member 400, the plurality of semiconductor chips 200 stacked from the lower surface 402 of the sealing member 400 in the sealing member 400, and the conductive wires 300 extending in a vertical direction from the lower surface of the sealing member 400 to the chip pads 210 of the plurality of the semiconductor chips 200. The chip pads 210 of the plurality of semiconductor chips 200 may be electrically connected to the upper substrate pads 122 of the package substrate 100 by the conductive wires 300 and the conductive bumps 350.

The conductive wires 300 may extend vertically and may not extend outward from one side of each of the plurality of semiconductor chips 200. When viewed from bottom view, the conductive wires 300 may be positioned in the area where the plurality of semiconductor chips 200 are disposed. According to comparative examples, bonding wires may extend outward from one side of a semiconductor chip and may be bonded to substrate pads of a package substrate. That is, a vertical space may be required for loop heights of the bonding wires, and since the bonding wires extend beyond the area where the semiconductor chip is placed, an outer area around the semiconductor chip may be required for the bonding wires.

According to some implementations, since the conductive wires 300 do not need an outer area around the semiconductor chips, the area and height of the sealing member 400 surrounding the conductive wires 300 may be formed to be smaller. Thus, it may be possible to implement a small form factor package. Further, since the conductive wires 300 extend in the vertical direction, the connection passages may become very short, thereby greatly reducing the inductance of the electrical signal path and improving electrical performance. Furthermore, since the encapsulation structure ES is stacked on the package substrate 100 via the conductive bumps 350, a separate redistribution wiring layer may not be required, thereby simplifying the package manufacturing process.

Hereinafter, a method of manufacturing the semiconductor package in FIG. 1 will be explained.

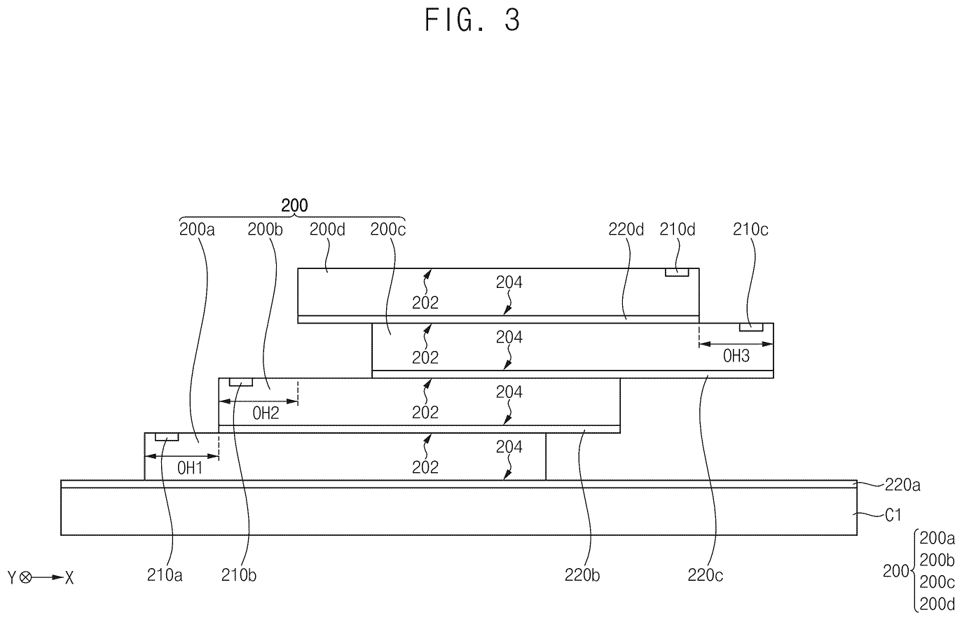

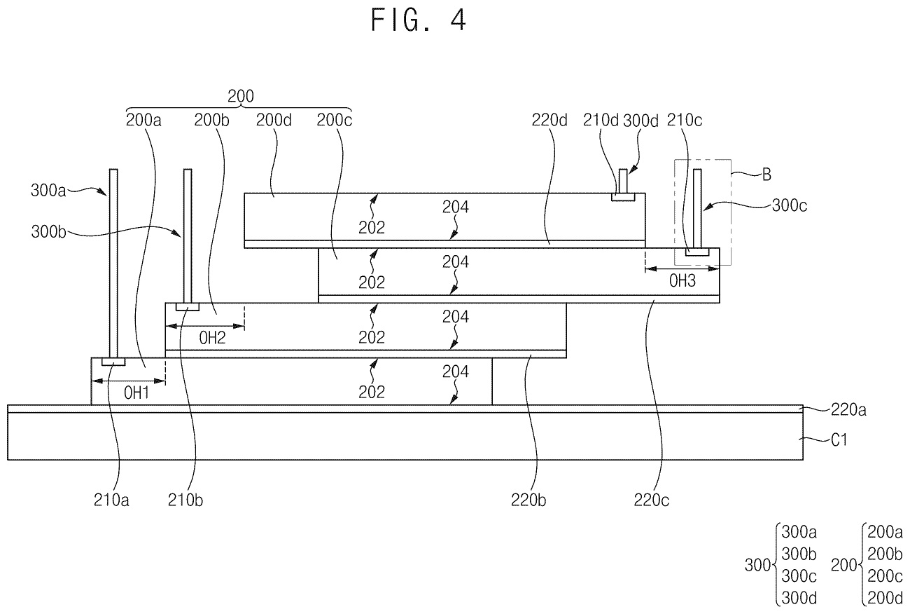

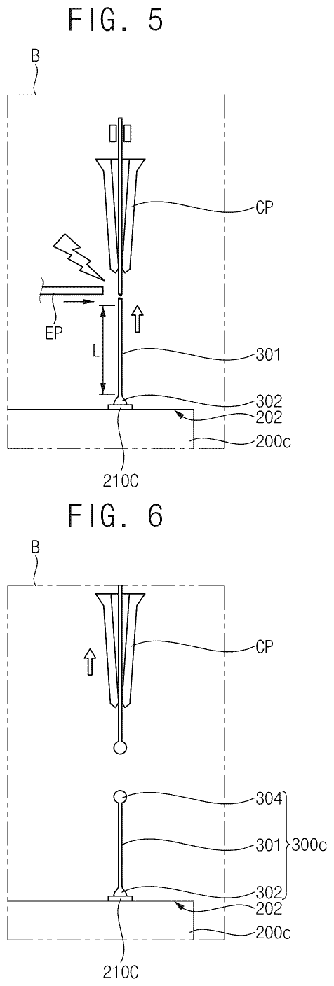

FIGS. 3 to 13 are views illustrating a method of manufacturing a semiconductor package in accordance with some implementations. FIGS. 5 and 6 are enlarged cross-sectional views illustrating a process of forming a vertical wire in portion ‘B’ of FIG. 4.

Referring to FIG. 3, a plurality of semiconductor chips 200 may be arranged on a carrier substrate C1.

In some implementations, four semiconductor chips 200a, 200b, 200c and 200d may be sequentially stacked on the carrier substrate C1. The carrier substrate C1 may include a glass substrate, a silicon substrate, a ceramic substrate, etc. For example, the carrier substrate C1 may be a wafer, and a plurality of semiconductor packages may be manufactured simultaneously on the carrier substrate C1. Individual semiconductor chips diced from a wafer by a dicing process may be provided as the semiconductor chips.

The semiconductor chips 200a, 200b, 200c, and 200d may be sequentially attached to an upper surface of the carrier substrate C1 using adhesive films 220a, 220b, 220c, and 220d. The semiconductor chips 200a, 200b, 200c, and 200d may be sequentially attached to the carrier substrate C1 using the adhesive films such as a die attach film (DAF) by a die attach process. For example, a thickness of the semiconductor chip may be within a range of 40 μm to 110 μm. A thickness of the adhesive film may be within the range of 10 μm to 60 μm.

The semiconductor chips 200a, 200b, 200c, and 200d may be arranged such that a backside surface 204 opposite to a front surface 202 on which chip pad 210a, 210b, 210c, and 210c are formed, that is, an inactive side faces the carrier substrate C1. Each of the semiconductor chips 200a, 200b, 200c, and 200d may have a quadrangular shape having four sides when viewed in plan view. The chip pads 210 may be disposed in a peripheral region along one side of each of the semiconductor chips 200a, 200b, 200c, and 200d.

In some implementations, the semiconductor chips 200a, 200b, 200c, and 200d may be stacked in a cascade structure on the carrier substrate C1. The second semiconductor chip 200b may be aligned with an offset in a first horizontal direction (X direction) on the first semiconductor chip 200a. The second semiconductor chip 200b may be offset aligned in the first horizontal direction (X direction) such that the chip pad 210a of the first semiconductor chip 200a is exposed from the second semiconductor chip 200b. The third semiconductor chip 200c may be aligned with an offset in the first horizontal direction (X direction) on the second semiconductor chip 200b. The third semiconductor chip 200c may be offset aligned in the first horizontal direction (X direction) such that the chip pad 210b of the second semiconductor chip 200b is exposed from the third semiconductor chip 200c. The fourth semiconductor chip 200d may be aligned with an offset in a direction opposite to the first horizontal direction (X direction) on the third semiconductor chip 200c. The fourth semiconductor chip 200d may be offset aligned in the direction opposite to the first horizontal direction (X direction) such that the chip pad 210c of the third semiconductor chip 200c is exposed from the fourth semiconductor chip 200d.

Each of the first, second, and third semiconductor chips 200a, 200b, 200c, and 200d has an overhang portion OH1, OH2, OH3 protruding from one side of each of the overlying second, third, and fourth semiconductor chips 200b, 200c, and 200d. When viewed from plan view, the chip pad 210a of the first semiconductor chip 200a may be arranged on an upper surface (that is, the front surface 202) of the overhang portion OH1 protruding from one side of the second, third, and fourth semiconductor chips 200b, 200c, and 200d to be spaced apart from each other along a second horizontal direction (Y direction) perpendicular to the first horizontal direction. When viewed from plan view, the chip pad 210b of the second semiconductor chip 200b may be arranged on an upper surface (that is, the front surface 202) of the overhang portion OH2 protruding from one side of the third and fourth semiconductor chips 200c and 200d to be spaced apart from each other along the second horizontal direction (Y direction). When viewed from plan view, the chip pad 210c of the third semiconductor chip 200c may be arranged on an upper surface (that is, the front surface 202) of the overhang portion OH3 protruding from one side of the fourth semiconductor chip 200d to be spaced apart from each other along the second horizontal direction (Y direction).

Each of semiconductor chips 200 may include a memory chip including a memory circuits. For example, the semiconductor chip may include volatile memory devices such as SRAM devices or DRAM devices, and non-volatile memory devices such as flash memory devices, PRAM devices, MRAM devices or RRAM devices.

It will be understood that the number, size, arrangement, etc. of the semiconductor chips are provided as an example, and the present disclosure is not limited thereto. Also, although only a few chip pads are illustrated in the figures, it will be understood that the structure, shape, and arrangement of the chip pads are provided as an example, and the present disclosure is not limited thereto.

Referring to FIGS. 4 to 6, conductive wires 300 as a plurality of vertical conductive structures may be formed on the plurality of semiconductor chips 200a, 200b, 200c, and 200d.

The conductive wires 300a, 300b, 300c, and 300d may be formed on the chip pads 210a, 210b, 210c, and 210d of the first, second, third, and fourth semiconductor chips 200a, 200b, 200c, and 200d, respectively.

In some implementations, the conductive wires 300 may be formed by a bonding wire process. The conductive wires 300 may be bonding wires formed by the bonding wire process.

As illustrated in FIGS. 5 and 6, after one end portion of a wire drawn from a capillary CP is bonded to the chip pad 210c of the third semiconductor chip 200c, the capillary CP may move in an upward vertical direction to withdraw the wire. The wire may be pulled out while moving in the vertical direction. Then, when the wire is extended by a predetermined length (L), a portion of the wire may be cut to form the conductive wire 300c. When cutting a portion of the wire, a free air ball FAB may be formed in the cut portion of the wire. For example, an Electronic Flame-Off (EFO) electrode (EP) may be moved adjacent to the cut portion (free end) of the wire and a spark may be generated between the EFO electrode (EP) and the cut portion of the wire to from a ball at a new free end.

Thus, the conductive wire 300c includes a wire body 301 extending in the vertical direction, a first bonding end portion 302 provided at a first end portion of the wire body 301 and bonded to the chip pad 210c, and a second bonding end portion 304 provided at a second end portion opposite to the first end portion of the wire body 301 and having a ball shape. The wire body 301 may have a first diameter, and the second bonding end portion 304 may have a second diameter that is greater than the first diameter. For example, the first diameter and the second diameter may be within a range of 15 μm to 200 μm.

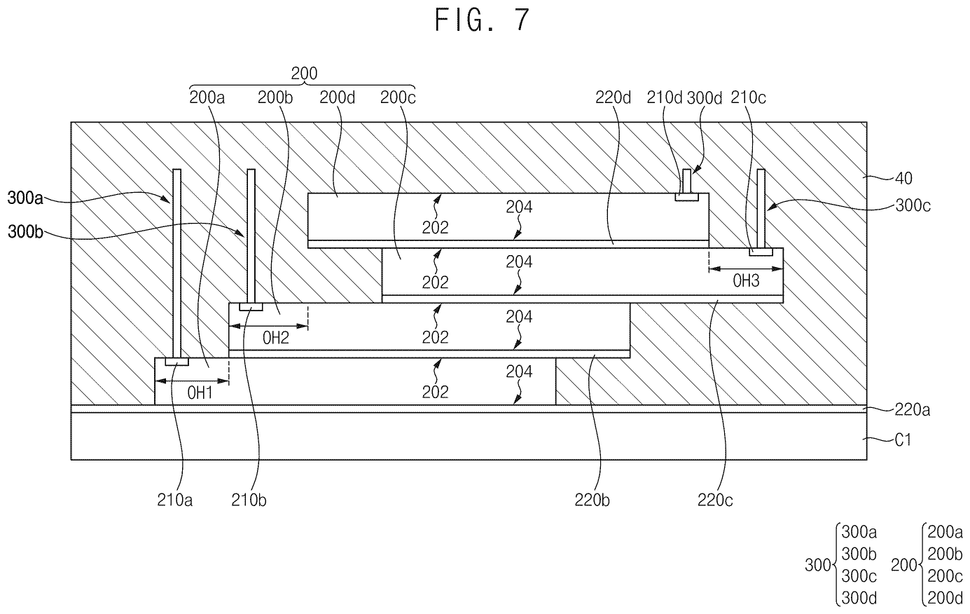

Referring to FIGS. 7 to 9, a sealing member 400 may be formed on the upper surface of the carrier substrate C1 to cover the plurality of semiconductor chips 200 and the conductive wires 300.

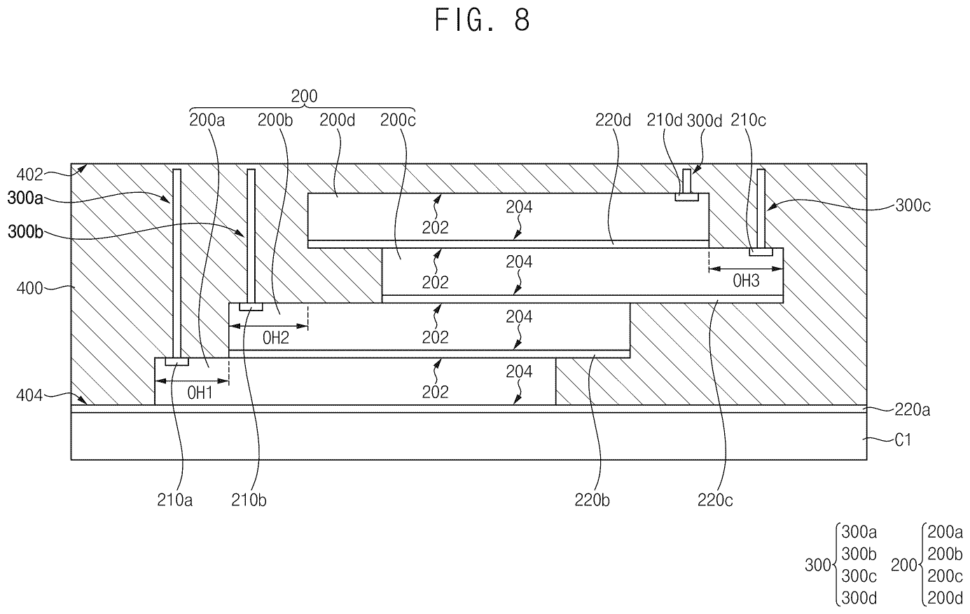

As illustrated in FIGS. 7 and 8, a sealing material 40 may be formed on the upper surface of the carrier substrate C1 to cover the plurality of semiconductor chips 200, and an upper portion of the sealing material 40 may be removed to form the sealing member 400 having a desired height. The sealing material 40 may be formed to completely cover the conductive wires 300. The sealing material 40 may include a thermosetting resin, for example, epoxy mold compound (EMC).

For example, an upper surface of the sealing material 40 may be removed by a mechanical chemical polishing process. Accordingly, the sealing member 400 may have a first surface 402 and a second surface 404 opposite to the first surface 402. At this time, end portions of the conductive wires 300, that is, the second bonding end portions 304 may not be exposed from the first surface 402 of the sealing member 400.

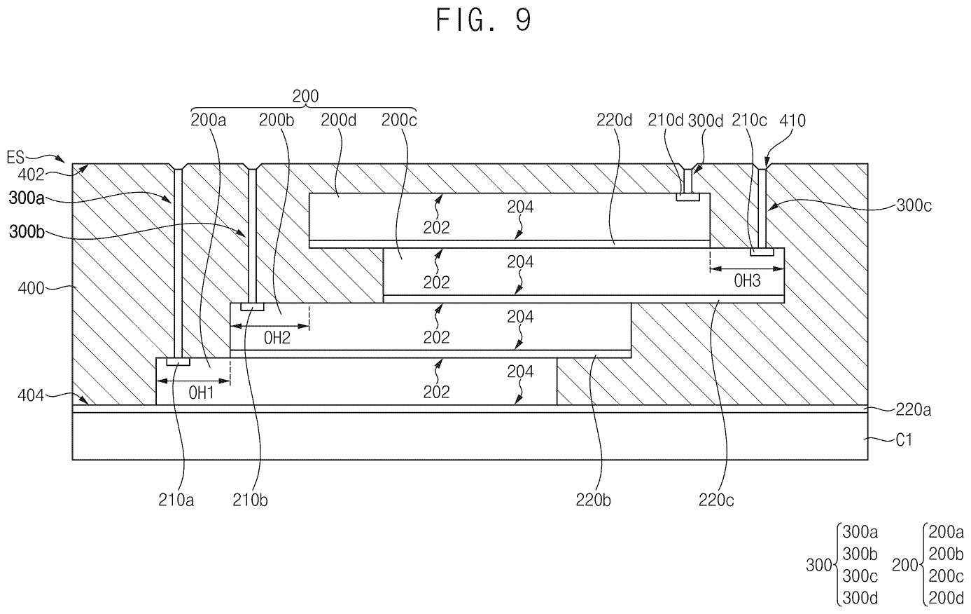

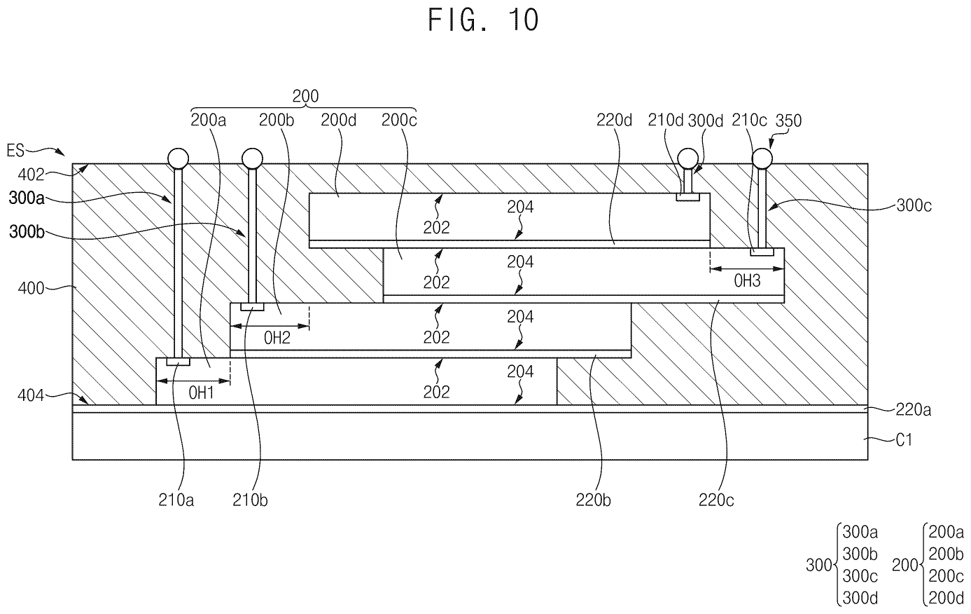

As illustrated in FIG. 9, recesses 410 may be formed in the first surface 402 of the sealing member 400 to expose the end portions of the conductive wires 300, that is, the second bonding end portions 304 respectively. For example, a laser drilling process may be performed on the first surface 402 of the sealing member 400 to form the recesses 410. A laser in the laser drilling process may include CO₂ laser, YAG laser, excimer laser, UV laser, etc.

The recesses 410 may have a predetermined depth from the first surface 402 of the molding member 400 and expose end portions of the plurality of conductive wires 300. The depth of the recess 410 may be within a range of 15 μm to 100 μm from the first surface 402 of the molding member 400.

Accordingly, an encapsulation structure ES including the sealing member 400 in which the plurality of semiconductor chips 200 is accommodated and the conductive wires 300 extending from the first surface 402 of the sealing member 400 to the chip pads 210 of the semiconductor chips 200 may be formed.

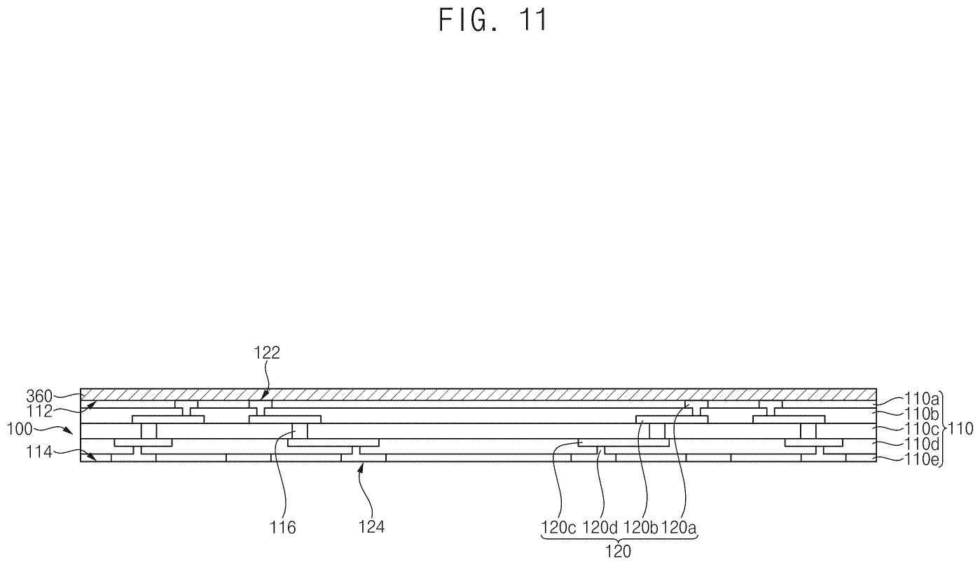

Referring to FIG. 10, conductive bumps 350 may be formed on the end portions of the conductive wires 300 of the encapsulation structure ES. The conductive bump 350 may include solder balls, solder bumps, solder paste, etc.

For example, a seed layer may be formed on the first side 402 of the sealing member 400 and the end portions of the conductive wires 300 in the recesses 410, and a photoresist pattern having openings that expose bump regions on the conductive wires 300 may be formed. Then, the opening of the photoresist pattern may be filled up with a conductive material, the photoresist pattern may be removed and a reflow process may be performed to form the conductive bump 350. For example, the conductive material may be formed on the seed layer by a plating process. Alternatively, the bump may be formed by a screen printing process, a deposition process, a solder ball attach process, etc.

Referring to FIG. 11, a package substrate 100 may be provided, and an adhesive layer 360 may be formed on the package substrate 100.

In some implementations, the package substrate 100 may be a multilayer circuit board having an upper surface 112 and a lower surface 114 opposite to the upper surface 112. The package substrate 100 may be a strip substrate for manufacturing a semiconductor strip, such as a printed circuit board (PCB). For example, the package substrate 100 may include a printed circuit board (PCB), a flexible substrate, a tape substrate, etc. The printed circuit board may be a multilayer circuit board having vias and various circuits therein.

In particular, the package substrate 100 includes first to fifth insulating layers 110a, 110b, 110c, 110d, and 110e sequentially stacked and first to fourth wirings 120a, 120b, 120c, and 120d provided in the first to fifth insulating layers. The first to fourth wirings 120a, 120b, 120c and 120d may be referred to as a first to fourth circuit layers stacked in a thickness direction from the upper surface 112 to the lower surface 114 of the package substrate 100. For example, the wiring may include metal materials such as copper, aluminum, etc. It will be understood that the arrangements and numbers of the insulating layers and the wirings are illustrative and not limited thereto.

A conductive through via 116 may penetrate the third insulating layer 110c as the core layer and electrically connect the second wiring 120b and the third wiring 120c. The first wiring 120a may be exposed from the upper surface 112 of the package substrate 100. The fourth wiring 120d may be exposed from the lower surface 114 of the package substrate 100.

The first insulating layer 110a as an upper protective layer may be formed on the upper surface 112 of the package substrate 100, and may expose at least a portion of the first wiring 120a. The exposed portion of the first wiring 120a may be provided as an upper substrate pad 122. The fifth insulating layer 110e as a lower protective layer may be provided on the lower surface 114 of the package substrate 100, and may expose at least a portion of the fourth wiring 120d. The exposed portion of the fourth wiring 120d may be provided as a lower substrate pad 124. The upper insulating layer 110a and the lower insulating layer 110e may separate the circuit patterns of the package substrate 100 from the external environment to prevent contamination and electrically insulate the wirings of the circuit patterns from each other. For example, the upper insulating layer and the lower insulating layer may include a photosensitive resin such as photo epoxy or a photosensitive polymer such as photo solder resist (PSR).

In some implementations, the adhesive layer 360 may be formed on the upper surface 112 of the package substrate 100. For example, the adhesive layer 360 may include a non-conductive film (NCF). The adhesive layer 360 may have a thickness within a range of 10 μm to 150 μm. The adhesive layer 360 may be used to attach the encapsulation structure ES to the package substrate 100 via the conductive bumps 300.

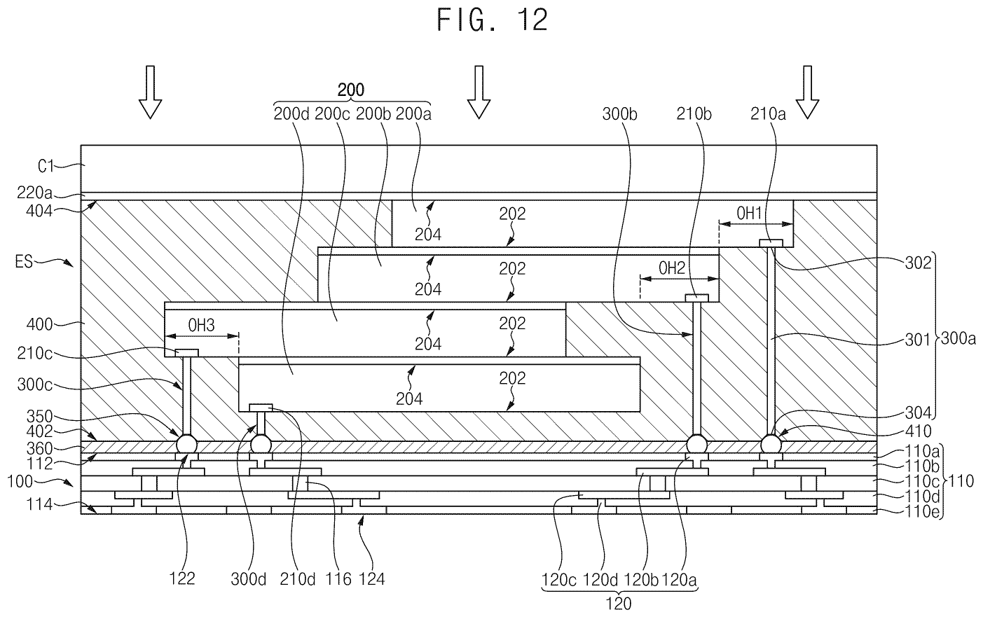

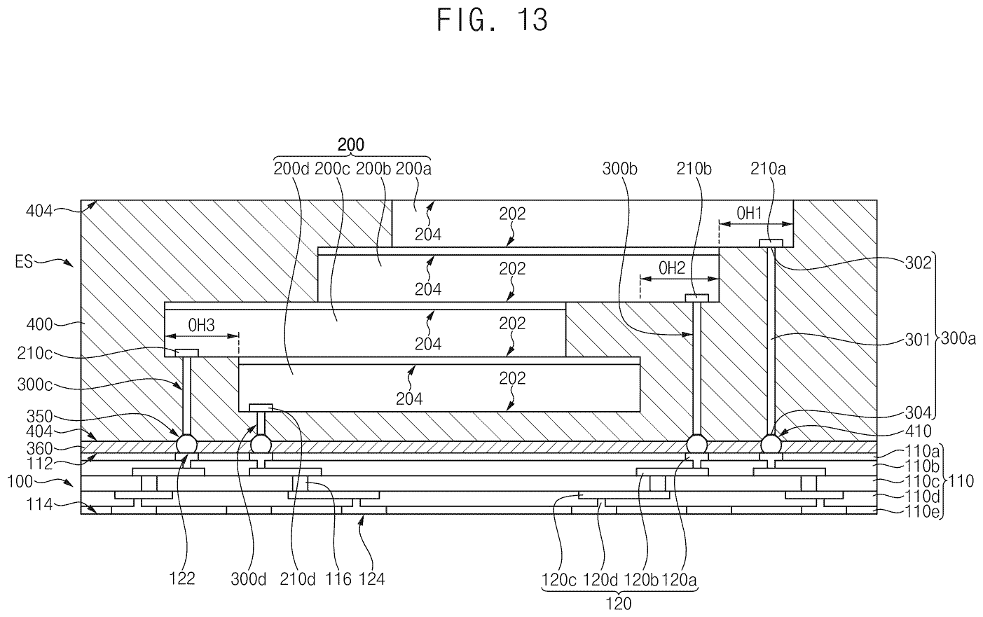

Referring to FIGS. 12 and 13, the encapsulation structure ES of FIG. 10 may be stacked on the package substrate 100. The encapsulation structure ES may be attached to the package substrate 100 using the adhesive layer 360.

As illustrated in FIG. 12, the package substrate 100 may be placed on a stage of a bonding apparatus, and the encapsulation structure ES of FIG. 10 may be adsorbed to a head of the bonding apparatus and then thermally compressed to the package substrate 100.

The adhesive layer 360 may be heated and the conductive bumps 350 may be reflowed to be interposed between upper bonding pads 122 of the package substrate 100 and the conductive wires 300. Accordingly, the package substrate 100 may be electrically connected to the semiconductor chips 200 through the conductive bumps 350 and the conductive wires 300.

Additionally, the adhesive layer 360 may be formed to fill spaces between the conductive bumps 300 between a lower surface of the encapsulation structure ES and the upper surface 112 of the package substrate 100. The adhesive layer 360 may cover a side surface of the conductive bump 350.

Thus, the encapsulation structure ES may be stacked on the package substrate 100 via the conductive bumps 300.

As illustrated in FIG. 13, the first carrier substrate C1 may be removed, and external connection members 500 (see FIG. 1) may be formed on the lower surface 114 of the package substrate 100 to complete the semiconductor package of FIG. 1.

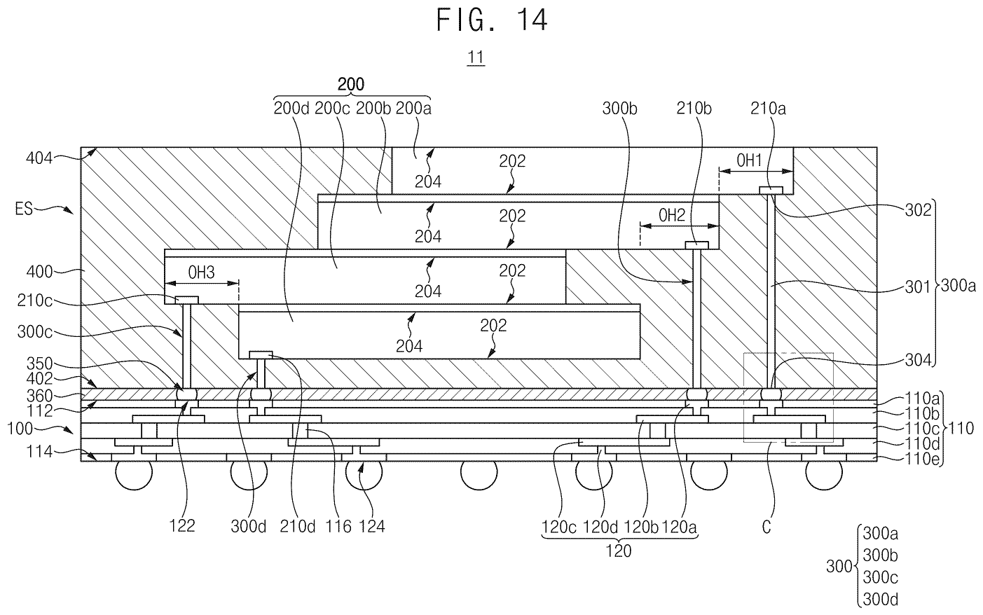

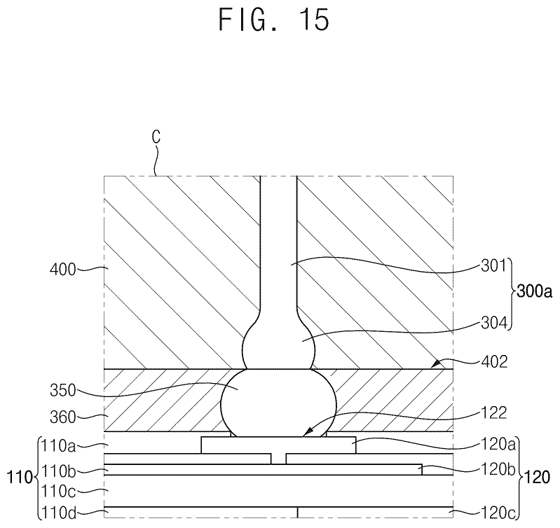

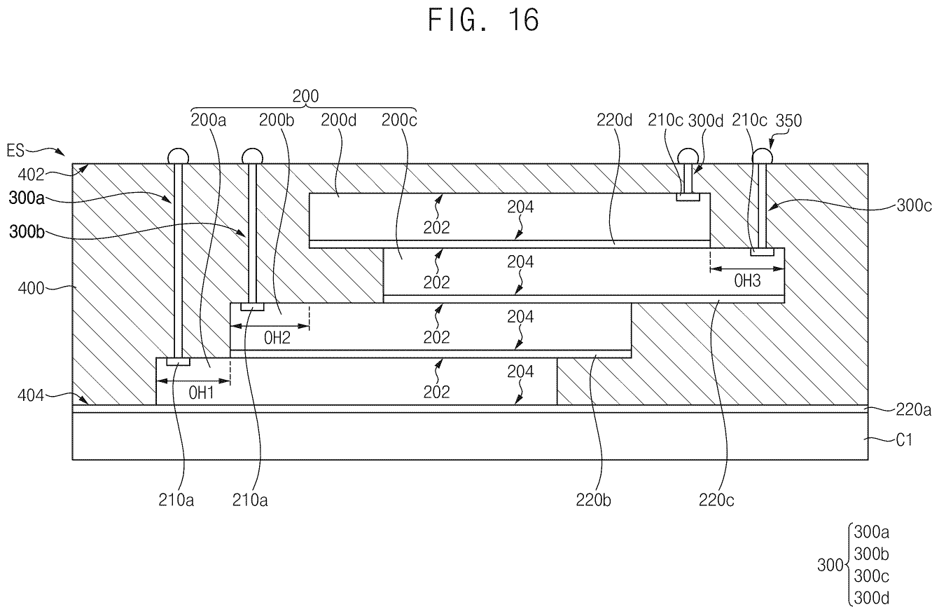

FIG. 14 is a cross-sectional view illustrating a semiconductor package in accordance with some implementations. FIG. 15 is an enlarged cross-sectional view illustrating a portion ‘C’ in FIG. 14. The semiconductor package may be substantially the same as or similar to the semiconductor package described with reference to FIG. 1 except for a connection configuration between conductive wires and conductive bumps. Thus, same reference numerals will be used to refer to the same or like elements and any further repetitive explanation concerning the above elements will be omitted.

Referring to FIGS. 14 and 15, a semiconductor package 11 includes a package substrate 100, an encapsulation structure ES disposed on the package substrate 100, a plurality of conductive bumps 350 disposed between the package substrate 100 and the encapsulation structure ES, and an adhesive layer 360 attaching the package substrate 100 and the encapsulation structure ES to each other. The encapsulation structure ES includes a sealing member 400, a plurality of semiconductor chips 200 disposed in the sealing member 400, and conductive wires 300 as a plurality of vertical conductive structures in the sealing member 400 and extending from chip pads 210 of the plurality of semiconductor chips 200.

In some implementations, the encapsulation structure ES including the sealing member 400 covering the plurality of semiconductor chips 200 and the plurality of conductive wires 300 may be stacked on the package substrate 100 via the conductive bumps 350. The encapsulation structure ES may be stacked on the package substrate 100 such that a lower surface 402 of the sealing member 400 faces the package substrate 100. The conductive bumps 350 may be interposed between the encapsulation structure ES and the package substrate 100. The conductive bumps 350 may be interposed between upper bonding pads 122 of the package substrate 100 and the conductive wires 300.

As illustrated shown in FIG. 15, the conductive wires 300 may extend in a vertical direction on the chip pads 210 of the first, second, third, and fourth semiconductor chips 200 within the sealing member 400, respectively. End portions of the conductive wires 300, that is, second bonding end portions 304 may be exposed from the lower surface 402 of the sealing member 400. Lower surfaces of the second bonding end portions 304 of the conductive wires 300 may be positioned on the same plane as the lower surface 402 of the sealing member 400.

Hereinafter, a method of manufacturing the semiconductor package of FIG. 14 will be described.

FIG. 16 is a cross-sectional view illustrating a method of manufacturing a semiconductor package in accordance with some implementations.

Referring to FIG. 16, first, processes the same as or similar to the processes described with reference to FIGS. 3 to 7 may be performed to place a plurality of semiconductor chips 200 on a carrier substrate C1, a plurality of conductive wires 300 may be formed on the plurality of semiconductor chips 200a, 200b, 200c and 200d, and a sealing material 40 may be formed on an upper surface of the carrier substrate C1 to cover the plurality of semiconductor chips 200. Then, an upper portion of the sealing material 40 may be removed to form a sealing member 400.

In some implementations, the upper portion of the sealing material 40 may be removed until end portions of the conductive wires 300, that is, second bonding end portions are exposed. Accordingly, the second bond end portions 304 of the conductive wires 300 may be exposed from a first surface 402 of the sealing member 400. Upper surfaces of the second bonding end portions 304 of the conductive wires 300 may be positioned on the same plane as a first surface 402 of the sealing member 400.

Thus, an encapsulation structure ES including the sealing member 400 in which the plurality of semiconductor chips 200 is accommodated and the conductive wires 300 extending from the first surface 402 of the sealing member 400 to chip pads 210 of the semiconductor chips 200 may be formed.

Then, processed the same as or similar to the processes described with reference to FIG. 10 may be performed to form conductive bumps 350 on the end portions of the conductive wires 300 of the encapsulation structure ES. The conductive bumps 350 may be formed on the end portions of the conductive wires 300 exposed from the first surface 402 of the sealing member 400, that is, the second bonding end portions.

Then, processes the same as or similar to the processes described with reference to FIGS. 11 to 13 may be performed to attach the encapsulation structure ES to the package substrate 100 via conductive bumps 300, and external connection members 500 (see FIG. 14) may be formed on a lower surface 114 of the package substrate 100 to complete the semiconductor package 11 of FIG. 14.

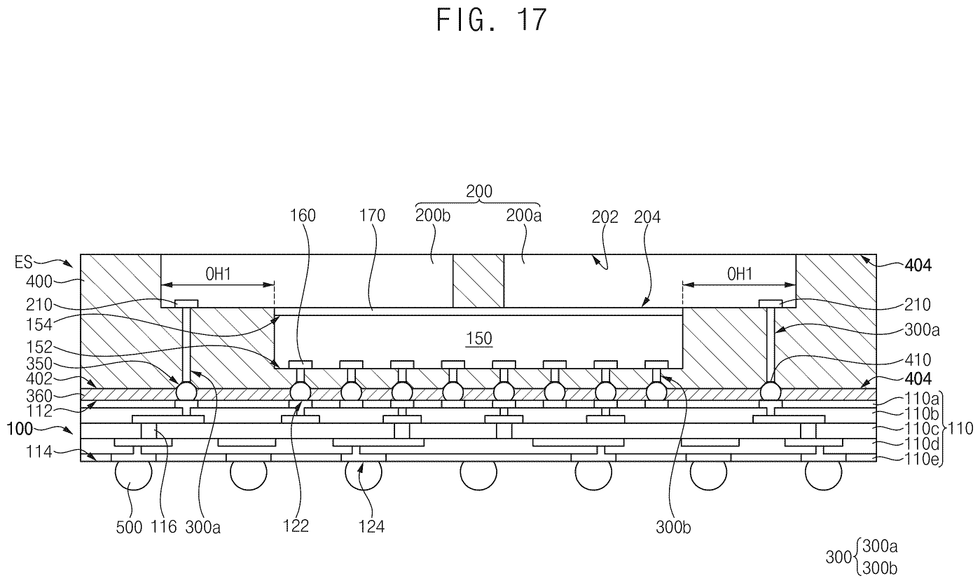

FIG. 17 is a cross-sectional view illustrating a semiconductor package in accordance with some implementations. The semiconductor package may be substantially the same as or similar to the semiconductor package described with reference to FIG. 1 except for a configuration of semiconductor chips in a molding member. Thus, same reference numerals will be used to refer to the same or like elements and any further repetitive explanation concerning the above elements will be omitted.

Referring to FIG. 17, a semiconductor package 12 includes a package substrate 100, an encapsulation structure ES disposed on the package substrate 100, a plurality of conductive bumps 350 disposed between the package substrate 100 and the encapsulation structure ES, and an adhesive layer 360 attaching the package substrate 100 and the encapsulation structure ES to each other. The encapsulation structure ES includes a sealing member 400, a processor chip 150 and a plurality of semiconductor chips 200 disposed within the sealing member 400, and conductive wires 300 as a plurality of vertical conductive structures extending on first chip pads 210 of the plurality of first semiconductor chips 200 and second chip pads 160 of the second semiconductor chip 150 within the sealing member 400.

Additionally, the semiconductor package 12 may be a multi-chip package (MCP) including different types of semiconductor chips. The semiconductor package 12 may be a System In Package (SIP) including a plurality of semiconductor chips stacked or arranged in one package to perform all or most of the functions of an electronic system.

In some implementations, the encapsulation structure ES includes the plurality of first semiconductor chips 200a and 200b spaced apart from each other at the same level from an upper surface 404 of the sealing member 400 and the processor chip 150 as a second semiconductor chip disposed on the plurality of first semiconductor chips 200a and 200b.

The second semiconductor chip 150 may be disposed in a first region of the molding member 400. The second semiconductor chip 150 may be disposed such that a front surface 152 on which the second chip pads 160 are formed, that is, an active surface, faces the package substrate 100. The second semiconductor chip 150 may have a rectangular shape with four sides when viewed in plan view. The second chip pads 160 may be arranged in an array form over the entire front surface 152 of the second semiconductor chip 150.

The second semiconductor chip 150 may be a logic chip including logic circuits. The logic chip may be a controller that controls memory chips. The second semiconductor chip may be a processor chip such as application-specific integrated circuit (ASIC) or an application processor AP of a host, such as central processing unit (CPU), graphic processing unit (GPU), or system-on-chip (SOC). For example, a thickness of the second semiconductor chip 150 may be within a range of 400 μm to 500 μm.

The plurality of first semiconductor chips 200 may be arranged on the second semiconductor chip 150 to be spaced apart from each other. The two first semiconductor chips 200a and 200b may be arranged at the same level on the second semiconductor chip 150. That is, two first semiconductor chips 200a and 200b may be stacked in one layer on the second semiconductor chip 150.

The first semiconductor chips 200a and 200b may be disposed such that a front surface 202 on which the first chip pads 210 are formed, that is, an active surface, faces the package substrate 100. Each of the first semiconductor chips 200a and 200b may have a rectangular shape with four sides when viewed in plan view. The first chip pads 210 may be disposed in a peripheral region along one side of each of the first semiconductor chips 200a and 200b. The peripheral regions of the first semiconductor chips 200a and 200b on which the first chip pads 210 are disposed may be arranged to face opposite directions.

The first semiconductor chips may include a memory chip including memory circuits. For example, the first semiconductor chip may include volatile memory devices such as SRAM devices, DRAM devices, etc. and non-volatile memory devices such as flash memory devices, PRAM devices, MRAM devices, RRAM devices, etc.

In some implementations, the first semiconductor chips 200 may be arranged such that the first chip pads 210 of each of the first semiconductor chips 200 are exposed by the second semiconductor chip 150. The peripheral regions of the first semiconductor chips 200a and 200b on which the first chip pads 210 are disposed may be exposed by the second semiconductor chip 150. Accordingly, each of the first semiconductor chips 200a and 200b may include an overhang portion OH1 protruding from one side of the second semiconductor chip 150, and the first chip pads 210 may be provided on a lower surface of the overhang portion OH1.

It will be understood that the number, size, and arrangement of the first and second semiconductor chips are provided as an example, and the present disclosure is not limited thereto. In addition, although only a few first and second chip pads are illustrated in the figures, it should be understood that the structure, shape and arrangement of the first and second chip pads are provided as an example, and the present disclosure is not limited thereto.

In some implementations, the conductive wires 300 includes first conductive wires 300a extending on the first chip pads 210 of the plurality of first semiconductor chips 200 and second conductive wires 300b extending on the second chip pads 160 of the second semiconductor chip 150.

In particular, the first conductive wire 300a may be a conductive wire that extends from the first chip pad 210 of the first semiconductor chips 200 toward a lower surface 402 of the sealing member 400. The second conductive wire 300b may be a conductive wire that extends from the second chip pad 160 of the second semiconductor chip 150 toward the lower surface 402 of the sealing member 400. Recesses may be provided in the lower surface 402 of the sealing member 400 to expose end portions of the conductive wires 300, respectively.

In some implementations, the encapsulation structure ES including the sealing member 400 covering the plurality of semiconductor chips 200 and the plurality of conductive wires 300 may be stacked on the package substrate 100 via the conductive bumps ES. The encapsulation structure ES may be stacked on the package substrate 100 such that the lower surface 402 of the sealing member 400 faces the package substrate 100.

The conductive bumps 350 may be interposed between the encapsulation structure ES and the package substrate 100. The conductive bumps 350 may be interposed between upper bonding pads 122 of the package substrate 100 and the conductive wires 300. The conductive bumps 350 and the first conductive wires 300a may electrically connect the first chip pads 210 of the first semiconductor chips 200 and wirings 120 of the package substrate 100. The conductive bumps 350 and the second conductive wires 300b may electrically connect the second chip pads 160 of the second semiconductor chip 150 and the wirings 120 of the package substrate 100. Portions of the conductive bumps 350 may be bonded to the exposed end portions of the conductive wires 300 in the recesses of the sealing member 400.

As mentioned above, the plurality of first semiconductor chips 200 may be arranged at the same level on the second semiconductor chip 150. The second semiconductor chip 150 and the plurality of first semiconductor chips 200 different from each other may be implemented into one package using the first and second conductive wires 300a and 300b as vertical conductive structures.

Accordingly, by using the first and second conductive wires, the overall thickness of the package may be reduced, the inductance of the signal path may be greatly reduced, and the number of input/output terminals may be increased with a fan-out structure.

Thus, the overall thickness and the area of the package may be reduced and the inductance of the signal path may be greatly reduced by using the first and second conductive wires.

Hereinafter, a method of manufacturing the semiconductor package of FIG. 17 will be described.

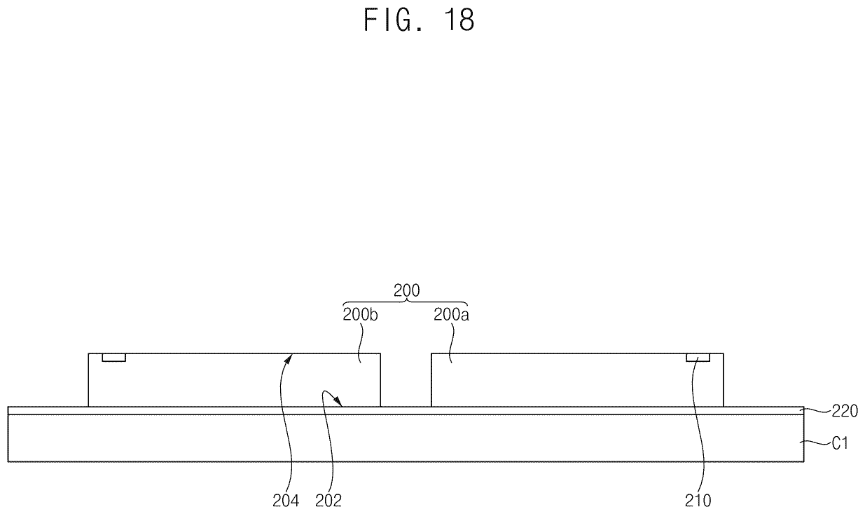

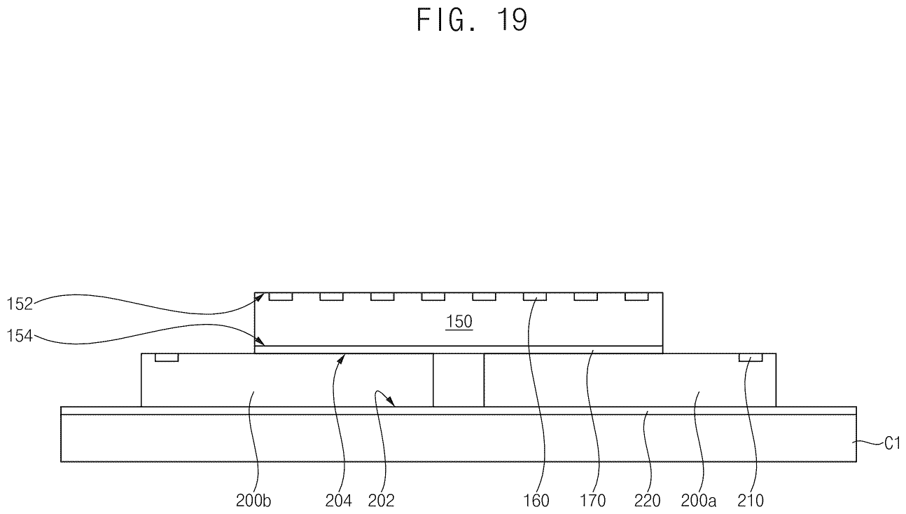

FIGS. 18 to 22 are views illustrating a method of manufacturing a semiconductor package in accordance with some implementations.

Referring to FIG. 18, a plurality of first semiconductor chips 200 may be disposed on a carrier substrate C1, and at least one second semiconductor chip 150 may be disposed on the plurality of first semiconductor chips 200.

In some implementations, two first semiconductor chips 200a and 200b may be arranged to be spaced apart from each other on the carrier substrate C1. The first semiconductor chips 200a and 200b may be attached to an upper surface of the carrier substrate C1 using a first adhesive member 220.

The first semiconductor chips 200a and 200b may be disposed such that a backside surface 204 opposite to a front surface 202 on which first chip pads 210 are formed, that is, an inactive side, faces the carrier substrate C1. The two first semiconductor chips 200a and 200b may be disposed at the same level on the carrier substrate C1. That is, the two first semiconductor chips 200a and 200b may be stacked in one layer on the carrier substrate C1.

Then, the second semiconductor chip 150 may be disposed on the plurality of first semiconductor chips 200 such that the first chip pads 210 of the first semiconductor chips 200 are exposed by the second semiconductor chip 150. When viewed in plan view, the second semiconductor chip 150 may be disposed in a rectangular support area provided by the plurality of first semiconductor chips 200. Accordingly, peripheral regions of the first semiconductor chips 200a and 200b on which the first chip pads 210 are disposed may be exposed by the second semiconductor chip 150.

The second semiconductor chip 150 may be attached to upper surfaces of the plurality of first semiconductor chips 200a and 200b using a second adhesive member 170. The second semiconductor chip 150 may be disposed such that a backside surface 154, opposite to a front surface 152 on which second chip pads 160 are formed, that is, an inactive surface, faces the carrier substrate C1.

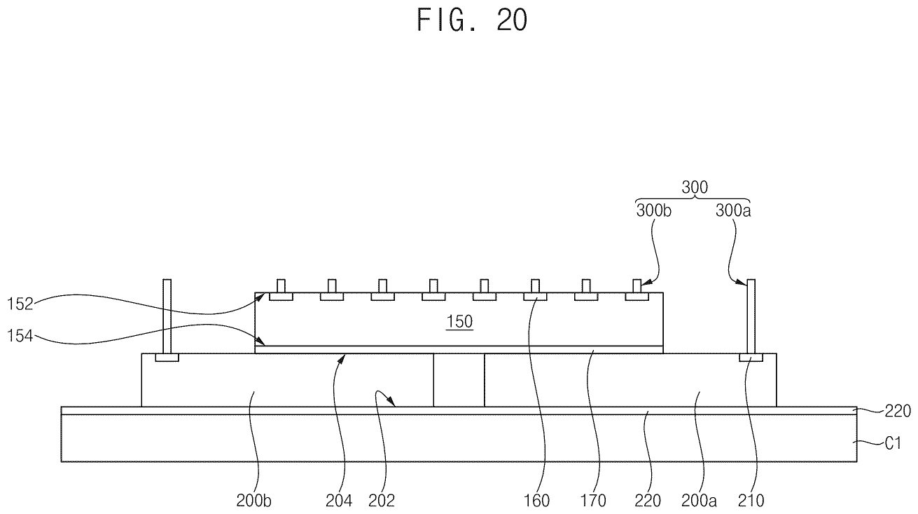

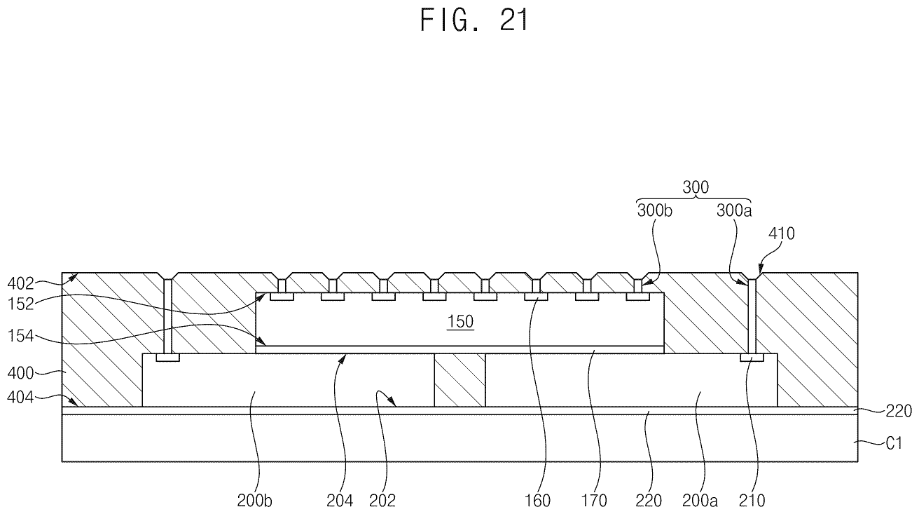

Referring to FIG. 20, processes the same as or similar to the processes described with reference to FIGS. 4 to 6 may be performed to form conductive wires 300 as a plurality of vertical conductive structures on the plurality of first semiconductor chips 200a and 200b and the second semiconductor chip 150. The first conductive wires 300a may be formed on the first chip pads 210 of the plurality of first semiconductor chips 200a and 200b, respectively, and the second conductive wires 300b may be formed on the second chip pads 160 of the second semiconductor chip 150, respectively.

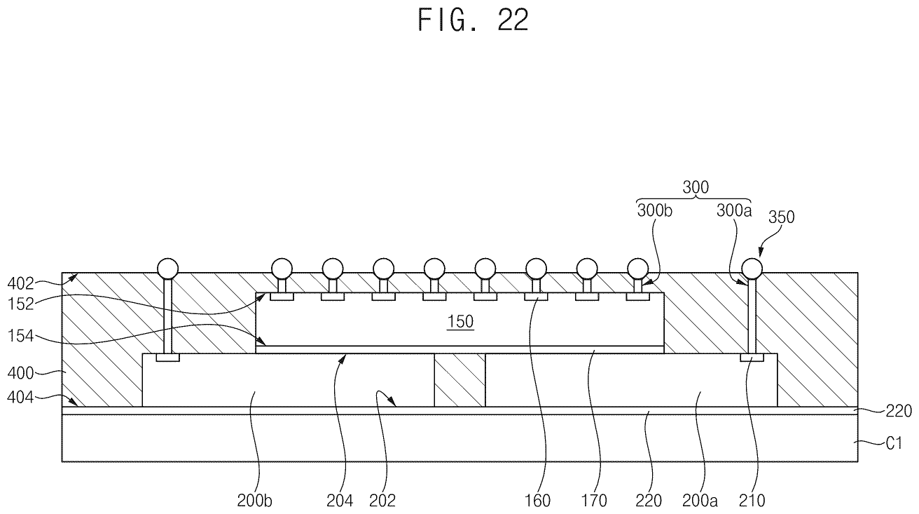

Referring to FIG. 21, processes the same as or similar to the processes described with reference to FIGS. 7 to 9 may be performed to form a sealing member 400 on the upper surface of the carrier substrate C1 to cover the plurality of first semiconductor chips 200, the second semiconductor chip 150 and the conductive wires 300.

For example, a sealing material 40 may be formed on the upper surface of the carrier substrate C1 to cover the plurality of first semiconductor chips 200, the second semiconductor chip 150, and the conductive wires 300, and an upper portion of the sealing material 40 may be removed to form the sealing member 400 having a desired height. Then, recesses 410 may be formed in a first surface 402 of the sealing member 400 to expose end portions of the conductive wires 300, that is, second bonding end portions 304.

Thus, an encapsulation structure ES including the sealing member 400 in which the plurality of first semiconductor chips 200 and the second semiconductor chip 150 are accommodated, the first conductive wires 300a extending from the first surface 402 of the sealing member 400 to the first chip pads 210 of the first semiconductor chips 200, and the second conductive wires 300b extending from the first surface 402 of the sealing member 400 to the second chip pads 160 of the second semiconductor chip 150.

Referring to FIG. 22, processes the same as or similar to the processes described with reference to FIG. 10 may be performed to form conductive bumps 350 on end portions of the conductive wires 300 of the encapsulation structure ES. Each of conductive bumps 350 may include a solder ball, a solder bump, a solder paste, etc.

Then, processes the same as or similar to the processes described with reference to FIGS. 11 to 13 may be performed to attach the encapsulation structure ES to the package substrate 100 via the conductive bumps 300, and external connection members 500 (see FIG. 17) may be formed on a lower surface 114 of the package substrate 100 to complete the semiconductor package 12 of FIG. 17.

The semiconductor package may include semiconductor devices such as logic devices or memory devices. The semiconductor package may include logic devices such as central processing units (CPUs), main processing units (MPUs), or application processors (APs), or the like, and volatile memory devices such as dynamic random-access memory (DRAM) devices, high bandwidth memory (HBM) devices, or non-volatile memory devices such as flash memory devices, hhase-change random access memory (PRAM) devices, magnetoresistive random-access memory (MRAM) devices, resistive random-access memory (ReRAM) devices, or the like.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of some implementations and is not to be construed as limiting thereof. Although a few implementations have been described, those skilled in the art will readily appreciate that many modifications are possible in some implementations without materially departing from the novel teachings and advantages of the present invention. Accordingly, all such modifications are intended to be included within the scope of implementations as defined in the claims.

What is claimed is:

1. A semiconductor package, comprising:
a package substrate;
an encapsulation structure stacked on the package substrate;
a plurality of conductive bumps disposed between the package substrate and the encapsulation structure; and
an adhesive layer attaching the package substrate and the encapsulation structure to each other,
wherein the encapsulation structure includes
a sealing member having an upper surface and a lower surface opposite to each other;
a plurality of semiconductor chips arranged in the sealing member such that a front surface of each semiconductor chip of the plurality of semiconductor chips faces the package substrate; and
a plurality of conductive wires extending from a lower surface of the sealing member to a plurality of chip pads of the plurality of semiconductor chips,
wherein the plurality of chip pads are formed on the front surfaces of the plurality of semiconductor chips, respectively, and
wherein the plurality of conductive bumps are disposed between the plurality of conductive wires and a plurality of substrate pads of the package substrate.

2. The semiconductor package of claim 1, wherein the adhesive layer includes a non-conductive film.

3. The semiconductor package of claim 1, wherein a plurality of recesses are provided in the lower surface of the sealing member to expose a plurality of end portions of the plurality of conductive wires, respectively, and
wherein a plurality of portions of the plurality of conductive bumps are bonded to the plurality of exposed end portions of the plurality of conductive wires in the plurality of recesses.

4. The semiconductor package of claim 1, wherein each conductive wire of the plurality of conductive wires includes:
a wire body extending in a vertical direction;
a first bonding end portion provided at a first end portion of the wire body and exposed from the lower surface of the sealing member; and
a second bonding end provided at a second end portion of the wire body and bonded to the chip pad.

5. The semiconductor package of claim 4, wherein the wire body has a first diameter and the first bonding end portion has a second diameter greater than the first diameter.

6. The semiconductor package of claim 1, wherein the conductive wire includes at least one of copper, gold, or aluminum.

7. The semiconductor package of claim 1, wherein the plurality of semiconductor chips include a first semiconductor chip, a second semiconductor chip, a third semiconductor chip, and a fourth semiconductor chip, wherein the first semiconductor chip, the second semiconductor chip, the third semiconductor chip, and the fourth semiconductor chip are stacked in a cascade structure from the upper surface of the sealing member,
wherein the first semiconductor chip includes a first overhang portion protruding from a side of the second semiconductor chip, the second semiconductor chip includes a second overhang portion protruding from a side of the third semiconductor chip, and the third semiconductor chip includes a third overhang portion protruding from a side of the fourth semiconductor chip, and
wherein a chip pad of the first semiconductor chip is provided on a lower surface of the first overhang portion, a chip pad of the second semiconductor chip is provided on a lower surface of the second overhang portion, and a chip pad of the third semiconductor chip is provided on a lower surface of the third overhang portion.

8. The semiconductor package of claim 7, wherein the first, second, third, and fourth semiconductor chips include one or more memory chips.

9. The semiconductor package of claim 1, wherein the plurality of semiconductor chips comprise a plurality of first semiconductor chips spaced apart from each other at a same level from the upper surface of the sealing member, and comprise a second semiconductor chip disposed on the plurality of first semiconductor chips,
wherein each of the plurality of first semiconductor chips includes an overhang portion protruding from one side of an underlying first semiconductor chip, and
wherein a chip pad of each first semiconductor chip of the plurality of first semiconductor chips is provided on a lower surface of the overhang portion.

10. The semiconductor package of claim 9, wherein the plurality of first semiconductor chips include a memory chip, and the second semiconductor chip includes a logic chip.

11. A semiconductor package, comprising:
a package substrate having a plurality of substrate pads on an upper surface of the package substrate;
a sealing member stacked on the upper surface of the package substrate via a plurality of conductive bumps that are disposed on the plurality of substrate pads;
a plurality of semiconductor chips stacked in the sealing member and arranged such that a front surface of each semiconductor chip of the plurality of semiconductor chips faces the package substrate; and
a plurality of conductive wires extending from a lower surface of the sealing member to a plurality of chip pads of the plurality of semiconductor chips,
wherein the plurality of chip pads are formed on the front surfaces of the plurality of semiconductor chips, respectively, and
wherein the plurality of conductive bumps are disposed between the plurality of conductive wires and the plurality of substrate pads.

12. The semiconductor package of claim 11, wherein a plurality of recesses are provided in the lower surface of the sealing member to expose a plurality of end portions of the plurality of conductive wires, respectively, and
wherein a plurality of portions of the plurality of conductive bumps are bonded to the plurality of exposed end portions of the plurality of conductive wires in the plurality of recesses.

13. The semiconductor package of claim 11, wherein each conductive wire of the plurality of conductive wires includes:
a wire body extending in a vertical direction;
a first bonding end portion provided at a first end portion of the wire body and exposed from the lower surface of the sealing member; and
a second bonding end portion provided at a second end portion of the wire body and bonded to the chip pad.

14. The semiconductor package of claim 13, wherein the wire body has a first diameter and the first bonding end portion has a second diameter that is greater than the first diameter.

15. The semiconductor package of claim 11, wherein the conductive wire includes at least one of copper, gold, or aluminum.

16. The semiconductor package of claim 11, wherein the plurality of semiconductor chips include a first semiconductor chip and a second semiconductor chip, wherein the first semiconductor chip and the second semiconductor chip are stacked in a cascade structure from the upper surface of the sealing member,
wherein the first semiconductor chip includes an overhang portion protruding from one side of the underlying second semiconductor chip, and
wherein one or more chip pads of the first semiconductor chip are provided on a lower surface of the overhang portion.

17. The semiconductor package of claim 11, wherein, when viewed from bottom, the plurality of conductive wires are disposed in an area where a plurality of semiconductor chips are disposed.

18. The semiconductor package of claim 11, further comprising:
an adhesive layer attaching the package substrate and the sealing member to each other.

19. The semiconductor package of claim 18, wherein the adhesive layer includes a non-conductive film.

20. A semiconductor package, comprising:
a package substrate having a plurality of substrate pads on an upper surface of the package substrate;
an encapsulation structure stacked on the package substrate, wherein the encapsulation structure includes
a sealing member having an upper surface and a lower surface opposite to each other,
a plurality of semiconductor chips stacked in the sealing member, offset aligned in a horizontal direction with respect to each other, and arranged such that a front surface of each semiconductor chip of the plurality of semiconductor chips faces the package substrate, and
a plurality of conductive wires extending from a lower surface of the sealing member to a plurality of chip pads of the plurality of semiconductor chips, wherein the plurality of chip pads are formed on the front surfaces of the plurality of semiconductor chips, respectively;
a plurality of conductive bumps disposed between the package substrate and the encapsulation structure and electrically connecting the substrate pads and the plurality of conductive wires; and
an adhesive layer attaching the package substrate and the encapsulation structure to each other.
